(19) United States
(12) Patent Application Publication
(10) Pub. No.: US 2025/0096171 A1
(43) Pub. Date: Mar. 20, 2025

(54) METHODS FOR BONDING WAFERS OF KNOWN GOOD DIES, AND ASSEMBLIES RESULTING FROM SUCH METHODS

(71) Applicant: Micron Technology, Inc., Boise, ID (US)

(72) Inventors: Bharat Bhushan, Taichung (TW); Akshay N. Singh, Boise, ID (US); Kunal R. Parekh, Boise, ID (US)

(21) Appl. No.: 18/789,049

(22) Filed: Jul. 30, 2024

Related U.S. Application Data
(60) Provisional application No. 63/539,270, filed on Sep. 19, 2023.

(51) Int. Cl. H01L 23/00; H01L 21/304; H01L 21/683; H01L 23/48; H01L 23/544; H01L 25/065; H10B 80/00

(52) U.S. Cl. CPC H01L 24/08; H01L 21/304; H01L 21/6835; H01L 23/481; H01L 24/05; H01L 24/89; H01L 24/94; H01L 23/544; H01L 25/0652; H01L 2221/68368; H01L 2223/5446; H01L 2224/05647; H01L 2224/08146; H01L 2224/89; H01L 2224/94; H01L 2924/1436; H10B 80/00

(57) ABSTRACT

A method of forming a semiconductor wafer is provided. The method includes dicing wafers into dies, testing the dies for known good dies, and bonding known good dies to a carrier wafer to form a top KGD wafer. The method also includes filling gaps between top dies to form a top gap-fill layer around and above each of the top dies, and bonding the top dies with a dummy silicon wafer. The method also includes bonding known good dies to carrier wafers to form one or more core KGD wafers, as well as filling gaps between the core dies to form a core gap-fill layer around each of the core dies. The method then includes bonding the one or more core KGD wafers to the top KGD wafer to form a KGD wafer stack.

### CROSS-REFERENCE TO RELATED APPLICATION(S)

The present application claims priority to U.S. Provisional Patent Application No. 63/539,270, filed Sep. 19, 2023, the disclosure of which is incorporated herein by reference in its entirety.

### TECHNICAL FIELD

The present disclosure generally relates to semiconductor device assemblies, and more particularly relates to methods for bonding wafers of known good dies, and assemblies resulting from such methods.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified schematic cross-sectional view of an example semiconductor device assembly.

FIG. 2 is a series of cross-sectional views illustrating a method of fabricating wafer stacks in accordance with an implementation of the present technology.

FIG. 3 is a partial schematic cross-sectional view of a wafer in accordance with embodiments of the present technology.

FIG. 4 is a simplified schematic cross-sectional view of a semiconductor device assembly in accordance with embodiments of the present technology.

FIG. 5 is a schematic view showing a system that includes a semiconductor device assembly configured in accordance with an embodiment of the present technology.

FIG. 6 is a flow chart illustrating a method of making a semiconductor device assembly in accordance with an embodiment of the present technology.

### DETAILED DESCRIPTION

The electronics industry relies upon continuous innovation in the field of semiconductor packaging to meet the global need for higher-functioning technology. This demand calls for increasingly complicated assemblies of semiconductor devices, which may diverge in terms of plan area, thickness, connection methodology, etc. One approach to accommodate the packaging of such varied devices into a single assembly is by bonding wafers into stacks, and then singulating the wafer stacks into discrete stacked assemblies.

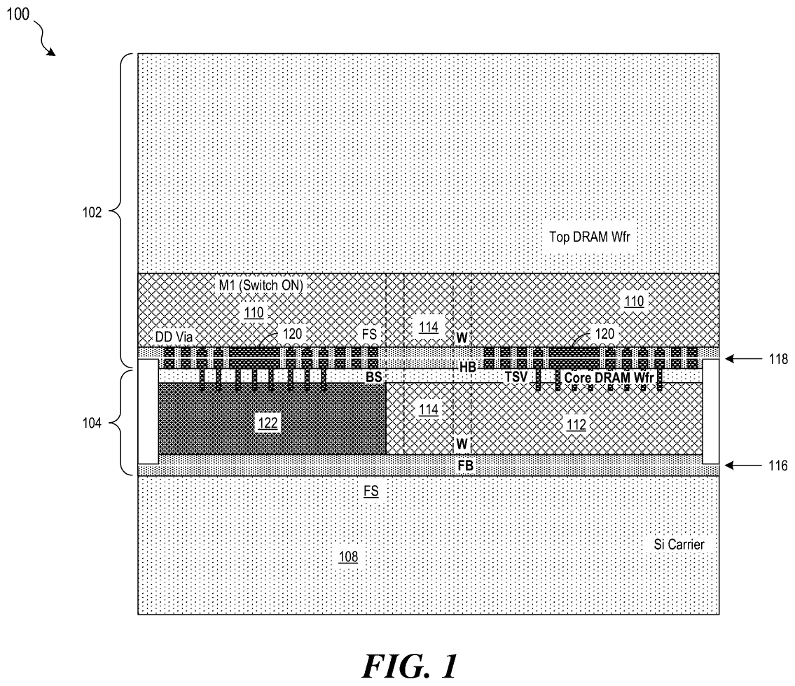

An example of one such wafer stack 100 is illustrated in FIG. 1. As can be seen with reference to FIG. 1, the wafer stack 100 can include a first wafer 102 comprised of top DRAM devices 110 bonded to a second wafer 104 comprised of core DRAM devices 112. Scribe areas 114 can exist between the top DRAM devices 110 as well as the core DRAM devices 112. The scribe areas 114 can contain scribe marks to assist with wafer alignment and bonding. The core DRAM devices 112 and the top DRAM devices 110 can have a similar orientation, in which the faces of the devices 110 and 112 are directed downwards. The bonding between wafers can be achieved by a hybrid bond 118 in which the faces of the top dram devices 110 are bonded to the backs of the core dram devices 112, the bonding achieved by way of pads 120 exposed on the bonding surfaces of both devices. Additionally, a fusion bond 116 can exist between the second wafer 104 and a silicon carrier wafer 108 below it.

Wafer stacks 100, however, have many disadvantages. One disadvantage of stacking wafers is the random distribution of bad dies 122 across a wafer surface. The presence of a single bad die 122 is enough to ruin an eventual device assembly formed from singulating the wafer stack 100. Therefore, as the number of wafers in a wafer stack 100 increases, the likelihood of at least one bad die 122 being introduced into an eventual device assembly increases exponentially.

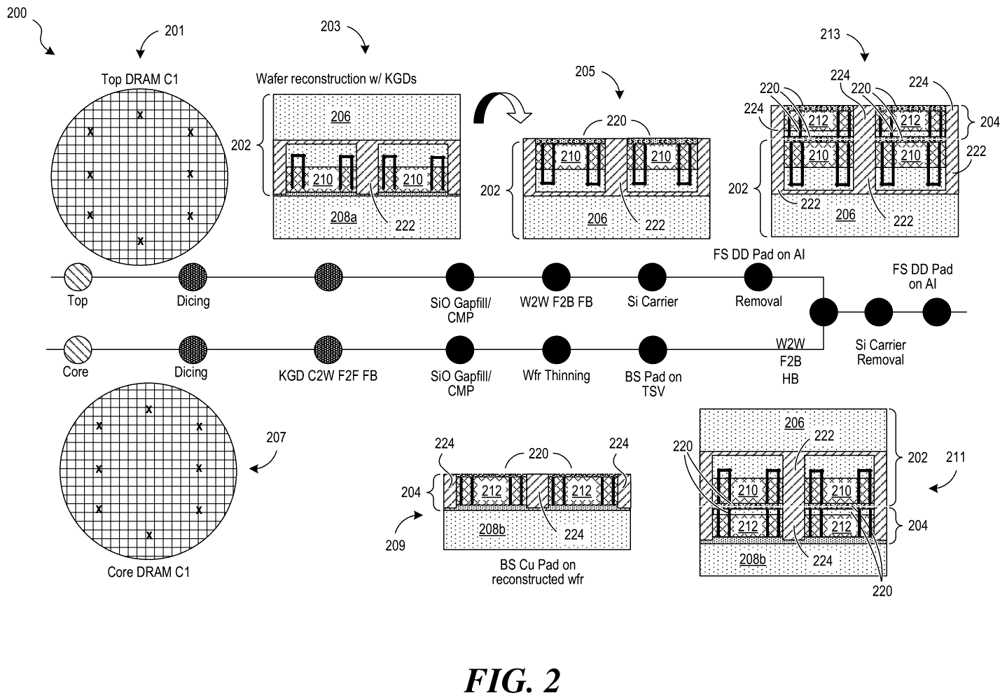

To address these drawbacks and others, various embodiments of the present disclosure provide methods for bonding wafers of known good dies, and the assemblies resulting from such methods. One method for bonding known-good-die (KGD) wafers to form a known-good-die (KGD) wafer stack is illustrated in FIG. 2. FIG. 2 is a series of cross-sectional views illustrating a method 200 of fabricating wafer stacks in accordance with an implementation of the present technology.

The method 200 can include a first step 201. The first step 201 can include dicing top semiconductor wafers into top semiconductor dies, and then testing the top semiconductor dies for known good dies. The method 200 can include a second step 203. The second step 203 can include bonding the known good dies to a top silicon carrier wafer 208a to form a top KGD wafer 202 comprising top dies 210. In some implementations, bonding known good dies to a first silicon carrier wafer 208a can include fusion bonding a face of each known good die (e.g., a top die 210) to a face of the silicon carrier wafer 208a.

The second step 203 can also include filling gaps between the top dies 208a with a gap-fill material such that the gap-fill material forms a top gap-fill layer 222 around and above each of the top dies 210. The gap-fill material can include a silicon oxide. Additionally, the second step 203 can include planarizing the top gap-fill layer 222 to form a level surface for bonding. The second step 203 can include bonding the top dies 210 with a dummy silicon wafer 206. In some implementations, bonding the top dies 210 with a dummy silicon wafer 206 can include fusion bonding a back of each top die 210 to a face of the dummy silicon wafer 206, the back of each top die including a portion of the top gap-fill layer 222. Additionally, or alternatively, forming the top KGD wafer 202 comprising top dies 210 can include thinning the dummy silicon wafer 206 of the top KGD wafer 202 to a desired height.

The method can include a third step 205, which can include removing the top silicon carrier wafer 208a to expose a face for each top die 210. The third step 205 can include forming pads 220 on the faces of the top dies 210. The method can include a fourth step 207. The fourth step 207 can include dicing core semiconductor wafers into core semiconductor dies, and then testing the core semiconductor dies for known good dies.

The method 200 can include a fifth step 209, which can include bonding known good dies to core silicon carrier wafers 208b to form one or more core KGD wafers 204 comprising core dies 212. In some implementations, bonding known good dies (e.g., core dies 212) to core silicon carrier wafers 208b can include fusion bonding a face of each core die 212 to a face of a core silicon carrier wafer 208b. Additionally, or alternatively, forming the one or more core KGD wafers 204 comprising core dies 212 can include thinning the core silicon carrier wafers 208b to a desired height.

The fifth step 209 can include filling gaps between the core dies 212 with the gap-fill material such that the gap-fill material forms a core gap-fill layer 224 around each of the core dies 212. Additionally, in some implementations, forming the core gap-fill layers can further include planarizing the core gap-fill layers such that the layers are coplanar with a top and a bottom of the core dies. The fifth step 209 can include forming pads 220 on a back of each core die 212.

The method 200 can include a sixth step 211, in which the one or more core KGD wafers 204 are bonded to the top KGD wafer 202 to form a KGD wafer stack. The method 200 can include a seventh step 213. The seventh step 213 can include removing the core silicon carrier wafers 208b to expose a face for each core die 212. The seventh step 213 can include forming pads 220 on the exposed faces of the core dies 212. Additionally, dummy pads can be formed on the top gap-fill layer 222 and the core gap-fill layers, in order to assist with planarization and prevent or reduce dishing of the gap-fill layers. Such dummy pads 420 can be evidence of a fabrication step in which they were disposed on the silicon oxide materials to assist with planarization (e.g., chemical mechanical planarization (CMP)), and to prevent or reduce dishing of the silicon oxide materials.

In some implementations, steps four through seven can be done to a single core KGD wafer selected from the one or more KGD wafers 204, or it can be done to all of the one or more core KGD wafers 204, either in parallel or sequentially. In those implementations in which the one or more core KGD wafers 204 are fabricated in parallel, the seventh step 213 can include hybrid bonding the pads 220 on the backs of the core dies 212 disposed below the pads on the faces of the core dies 212 disposed above them, and fusion bonding the core gap-fill 224 layers together, such that the one or more core KGD wafers 204 forms a stack of core KGD wafers. The seventh step 213 can then include bonding this stack of core KGD wafers 204 to the top KGD wafer 202. Alternatively, bonding the one or more core KGD wafers 204 to the top KGD wafer 202 can include selecting a core KGD wafer from the one or more core KGD wafers 204. In these implementations, bonding can include hybrid bonding the pads 220 on the backs of the core dies 212 to the pads on the faces of the top dies 210, and fusion bonding the top gap-fill layers 222 to the core gap-fill layers 224. Additionally, in certain implementations, the bonded core KGD wafer can be a bottom wafer in the KGD wafer stack, and the method 200 can include removing the core silicon carrier wafer 208b from the bottom wafer to expose a face for each core die 212 on the bottom wafer. These implementations can include forming pads 220 on the faces of the core dies 212 on the bottom wafer and bonding the bottom wafer to a core KGD wafer from the one or more core KGD wafers 204. The one or more core KGD wafers 204 can be sequentially bonded in a like manner until a desired height for the KGD wafer stack is reached. In these implementations, bonding the bottom wafer to a core KGD wafer can include hybrid bonding the pads 220 on the backs of the core dies 212 belonging to the core KGD wafer to the pads 220 on the faces of the core dies 212 belonging to the bottom wafer, and fusion bonding the core gap-fill layers 224 of both wafers together.

After the seventh step 213, the method 200 can include bonding an IF logic wafer to a bottom of the KGD wafer stack. Additionally, or alternatively, the method 200 can include singulating the KGD wafer stack into a plurality of stacked semiconductor device assemblies, wherein each assembly has fusion bonds between gap-fill layers and hybrid bonds between dies.

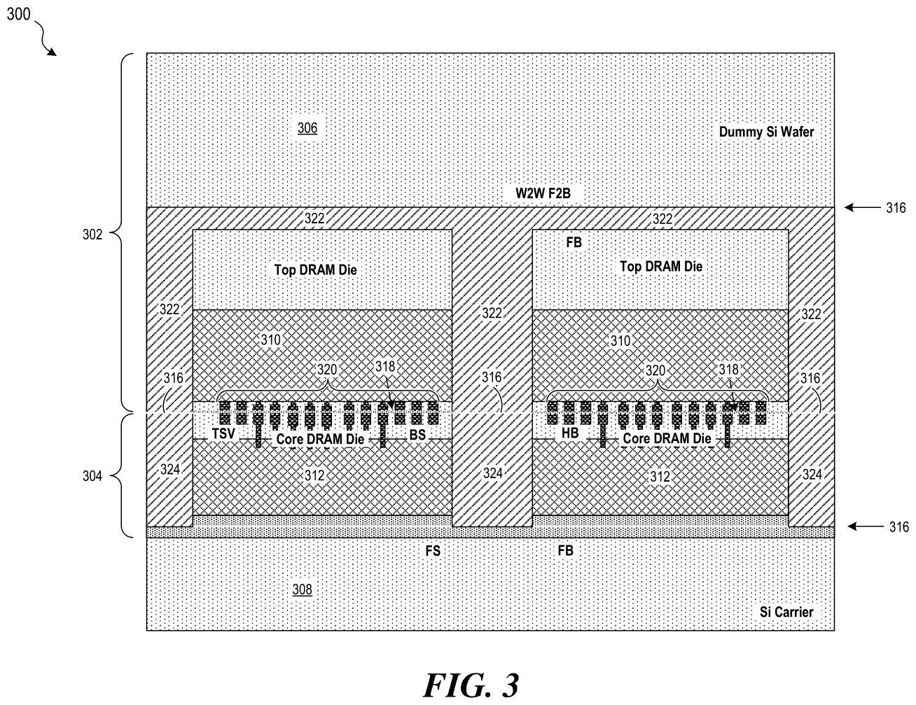

Illustrated in FIG. 3 is a partial schematic cross-sectional view of a wafer 300 in accordance with embodiments of the present technology. Such a wafer 300 can be produced by the foregoing method 200, specifically a detailed snapshot of the wafer 300 by step six 211. The wafer can include one or more core wafers 304, each core wafer 304 comprising core dies 312, and each core die having a front side facing downward. Each core die 312 can be surrounded peripherally by a first silicon oxide material 324 that is coplanar with a top and a bottom of the core die 312. Although it is only illustrated with a single core wafer 304, the wafer 300 can include multiple core wafers 304 stacked atop each other, and each core wafer 304 can include core dies 312 separated and surrounded by first silicon oxide materials 324. The wafer 300 can also include a top wafer 302 comprising top dies 310, the top dies having a front side facing downward and surrounded peripherally by a second silicon oxide material 322 that is coplanar with a bottom of the top dies 310. The second silicon oxide material 322 can also overlie the top dies 310. The wafer 300 can include a dummy silicon wafer 306 over the top dies 310, separated from the top dies 310 by the second silicon oxide material 322 overlying the top dies 310. The wafer 300 can include hybrid bonds 318 between each top die 310 and a core die 312. Additionally, in those embodiments in which multiple core wafers 304 are stacked below the top wafer 302, hybrid bonds 318 exist between the core dies 312 as well. The hybrid bonds 318 can include a top hybrid bond between core dies 312 from a core wafer from the one or more core wafers 304 and the top dies 310, as well as core hybrid bonds between the core dies belonging to the one or more core wafers, disposed below the top wafer 302 and the core wafer hybrid bonded to it. The wafer 300 includes fusion bonds 316 between the silicon oxide materials, as well as between each top die 310 and the dummy silicon wafer 306. Additionally, the wafer can include a silicon carrier wafer 308 disposed below a bottommost core wafer 304, as illustrated. In such embodiments, fusion bonds 316 can exist between the silicon carrier wafer 308 and the bottommost core wafer 304. The fusion bonds 316 can include top fusion bonds between the top dies 310 and the dummy silicon wafer 306, as well as core fusion bonds between the first silicon oxide material 322 and the second silicon oxide material 324.

Additionally, the front side of the top die 310 can have pads 320. Each core die 312 can have a back side that is opposite to its front side. Each core die 312 can have pads 320 on its back side and front side. In such embodiments, the top hybrid bond can be between the pads 320 on the front side of the top die 310 and the back side of the core die 312 disposed beneath it. The core hybrid bonds can be between the pads 320 on the front sides of the core dies 312 and the pads on the back sides of the core dies 312 disposed beneath. further comprising a silicon carrier wafer disposed beneath the one or more core dies, wherein the silicon carrier wafer is fusion bonded to a front side of a bottommost core die. In certain embodiments, an IF logic wafer can be disposed below the bottommost core die 412 and connected to the semiconductor device assembly 400.

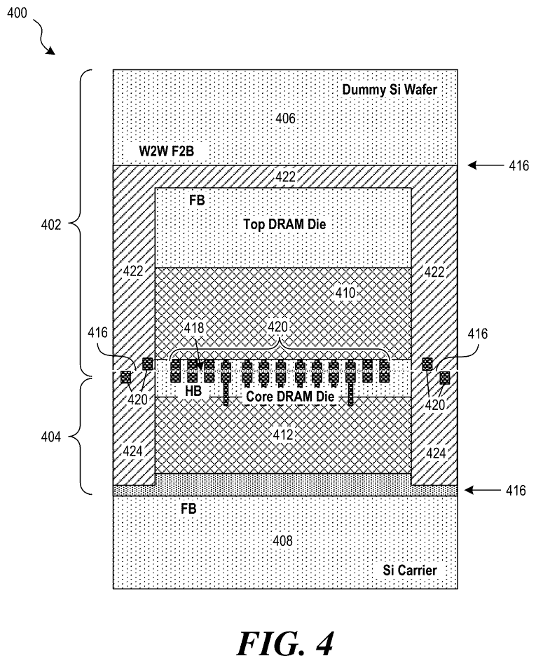

Such a wafer 300 can be singulated into a plurality of stacked semiconductor device assemblies, as discussed in the method 200 as being an optional step following the seventh step 213. FIG. 4 is a simplified schematic cross-sectional view of an example semiconductor device assembly 400 resulting from such an implementation, in accordance with embodiments of the present technology. The assembly 400 includes one or more core dies 412, each core die 412 having a front side facing downward, and each core die 412 being surrounded peripherally by a first silicon oxide material 424 that is coplanar with a top and a bottom of the core die 412. The assembly 400 also includes a top die 410, the top die 410 having a front side facing downward, and the top die 410 being surrounded peripherally by a second silicon oxide material 422 that is coplanar with a bottom of the top die 410 and that also overlies a top of the top die 410. The assembly 400 can also include a dummy silicon chip 406 over the top die 410, separated from the top die 410 by the second silicon oxide material 422 overlying the top die 410. The dummy silicon chip 406 can have sidewalls that are coplanar with an outer edge of the peripheral first and second silicon oxide materials 424 and 422. The assembly 400 includes a hybrid bond 418 between the top die 410 and a core die 412, as illustrated. Additionally, in those embodiments with multiple core dies 412 stacked below the top die 410, the assembly can include hybrid bonds 418 between the core dies 412. The hybrid bonds 418 can include a top hybrid bond between the core die 412 and the top die 410, as well as core hybrid bonds between the core dies 412 disposed below. The assembly 400 also includes fusion bonds between the silicon oxide materials, and between the top die 410 and the dummy silicon wafer 406. Additionally, the assembly 400 can include a silicon carrier wafer 408 disposed below a bottommost core die 412, as illustrated. In such embodiments, a fusion bond 416 can exist between the silicon carrier wafer 408 and the bottommost core die 412. In certain embodiments, a controller device can be disposed below the bottommost core die 412 and connected to the semiconductor device assembly 400. The fusion bonds 416 can include a top fusion bond between the top die 410 and the dummy silicon chip 406, as well as core fusion bonds between the first silicon oxide material 422 and the second silicon oxide material 424.

Additionally, in certain embodiments, the front side of the top die 410 can have pads 420. Each core die 412 can have a back side that is opposite to its front side. In such embodiments, the back side and the front side of each core die 412 can have pads 420. In such embodiments, the top hybrid bond can be between the pads 420 on the front side of the top die 410 and the back side of the core die 412 disposed beneath it. The core hybrid bonds can be between the pads 420 on the front sides of the core dies 412 and the pads 420 on the back sides of the core dies 412 disposed beneath. Additionally, dummy pads 426 can exist on the first and second silicon oxide materials 424 and 422, as illustrated. Such dummy pads 420 can be evidence of a fabrication step in which they were disposed on the silicon oxide materials to assist with planarization (e.g., chemical mechanical planarization (CMP)), and to reduce dishing of the silicon oxide materials.

Although in the foregoing example embodiment semiconductor device assemblies have been illustrated and described as including a single semiconductor device, in other embodiments assemblies can be provided with additional semiconductor devices. For example, the single semiconductor devices illustrated in FIGS. 2, 3, and/or 4 could be replaced with, e.g., a vertical stack of semiconductor devices, a plurality of semiconductor devices, mutatis mutandis.

In accordance with one aspect of the present disclosure, the semiconductor devices illustrated in the assemblies of FIGS. 2-4 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

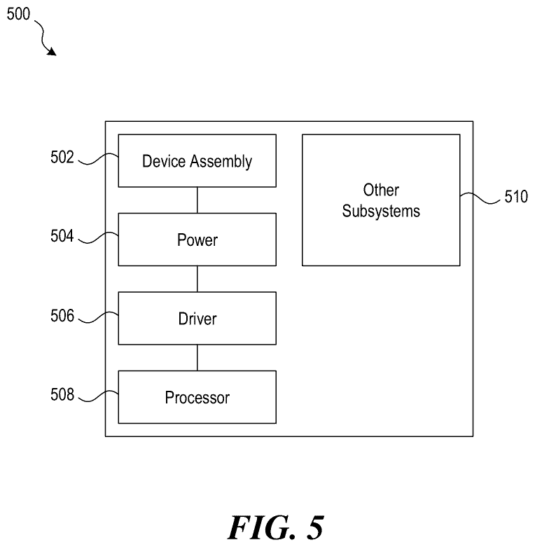

Any one of the semiconductor devices and semiconductor device assemblies described above with reference to FIGS. 2-4 can be incorporated into any of a myriad of larger and/or more complex systems, a representative example of which is system 500 shown schematically in FIG. 5. The system 500 can include a semiconductor device assembly (e.g., or a discrete semiconductor device) 502, a power source 504, a driver 506, a processor 508, and/or other subsystems or components 510. The semiconductor device assembly 502 can include features generally similar to those of the semiconductor devices described above with reference to FIGS. 2-4. The resulting system 500 can perform any of a wide variety of functions, such as memory storage, data processing, and/or other suitable functions. Accordingly, representative systems 500 can include, without limitation, hand-held devices (e.g., mobile phones, tablets, digital readers, and digital audio players), computers, vehicles, appliances and other products. Components of the system 500 may be housed in a single unit or distributed over multiple, interconnected units (e.g., through a communications network). The components of the system 500 can also include remote devices and any of a wide variety of computer readable media.

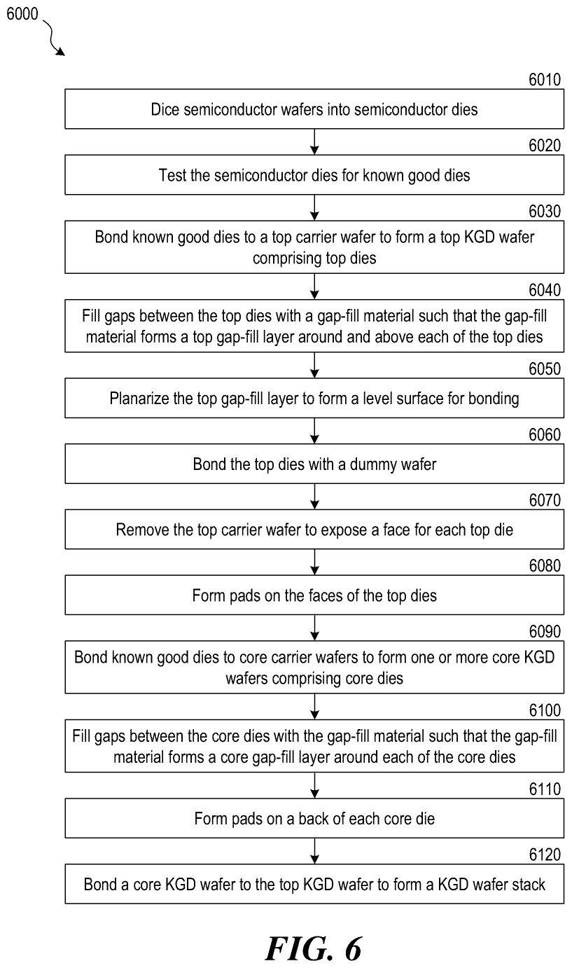

FIG. 6 is a flow chart illustrating a method 6000 of making a semiconductor device assembly. The method includes dicing semiconductor wafers into semiconductor dies (box 6010). The method includes testing the semiconductor dies for known good dies (box 6020). The method includes bonding known good dies to a top silicon carrier wafer to form a top KGD wafer comprising top dies (box 6030). The method includes filling gaps between the top dies with a gap-fill material such that the gap-fill material forms a top gap-fill layer around and above each of the top dies (box 6040). The method includes planarizing the top gap-fill layer to form a level surface for bonding (box 6050). The method includes bonding the top dies with a dummy silicon wafer (box 6060). The method includes removing the top silicon carrier wafer to expose a face for each top die (box 6070). The method includes forming pads on the faces of the top dies (box 6080). The method includes bonding known good dies to core silicon carrier wafers to form one or more core KGD wafers comprising core dies (box 6090). The method includes filling gaps between the core dies with the gap-fill material such that the gap-fill material forms a core gap-fill layer around each of the core dies (box 6100). The method includes forming pads on a back of each core die (box 6110). The method includes bonding the one or more core KGD wafers to the top KGD wafer to form a KGD wafer stack (box 6120).

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method for bonding known-good-die (KGD) wafers to form a known-good-die (KGD) wafer stack, comprising:
bonding a plurality of previously-tested top dies to a top silicon carrier wafer to form a temporary KGD wafer comprising the plurality of top dies;
filling gaps between the plurality of top dies with a gap-fill material such that the gap-fill material forms a top gap-fill layer around and above each of the plurality of top dies;
planarizing the top gap-fill layer to form a level surface for bonding;
bonding the temporary KGD wafer to a dummy silicon wafer, wherein the level surface of the top gap-fill layer directly contacts the dummy silicon wafer;
removing the top silicon carrier wafer to form a top KGD wafer and to expose a face of each of the plurality of top dies;
planarizing the top KGD wafer to prepare it for bonding;
bonding a plurality of previously-tested cored dies to one or more core silicon carrier wafers to form one or more core KGD wafers comprising the plurality of core dies;
filling gaps between the plurality of core dies with the gap-fill material such that the gap-fill material forms a core gap-fill layer around each of the plurality of core dies;
planarizing the one or more core KGD wafers to prepare them for bonding; and
forming a KGD wafer stack by bonding the one or more core KGD wafers to the top KGD wafer, wherein the bonding includes hybrid bonding backs of the core dies to the faces of the top dies, and fusion bonding the core gap-fill layer to the top gap-fill layer.

2. The method of claim 1, wherein forming the KGD wafer stack further comprises:
removing the core silicon carrier wafers from the one or more core KGD wafers to expose a face for each of the corresponding plurality of core dies; and
bonding each core KGD wafer from the one or more core KGD wafers to a bottommost core KGD wafer on the KGD wafer stack, wherein the bonding includes hybrid bonding the faces of core dies from the bottommost core KGD wafer to the backs of core dies from a core KGD wafer being added to the KGD wafer stack, and fusion bonding the core gap-fill layers together, and wherein the core KGD wafer being added to the KGD wafer stack becomes a new bottommost core KGD wafer.

3. The method of claim 1, wherein bonding the plurality of previously-tested top dies to the top silicon carrier wafer comprises fusion bonding a face of each previously-tested top die to a surface of the silicon carrier wafer.

4. The method of claim 1, wherein bonding the temporary KGD wafer to the dummy silicon wafer comprises fusion bonding a back of each of the plurality of top dies to a surface of the dummy silicon wafer, the back of each top die including a portion of the top gap-fill layer.

5. The method of claim 1, wherein bonding the plurality of previously-tested core dies to the one or more core silicon carrier wafers comprises fusion bonding a face of each of the plurality of core dies to a surface of a core silicon carrier wafer.

6. The method of claim 1, further comprising forming dummy pads on the top gap-fill layer, wherein the dummy pads are configured to prevent dishing of the top gap-fill layer during planarization.

7. The method of claim 1, further comprising forming dummy pads on the core gap-fill layer, wherein the dummy pads are configured to prevent dishing of the core gap-fill layer during planarization.

8. The method of claim 1, further comprising bonding an IF logic wafer to a bottom of the KGD wafer stack.

9. The method of claim 1, wherein forming one or more core KGD wafers further comprises thinning the core silicon carrier wafer of each of the one or more core KGD wafers to a desired height.

10. The method of claim 1, further comprising singulating the KGD wafer stack into a plurality of stacked semiconductor device assemblies, wherein each assembly has fusion bonds between adjacent gap-fill layers and hybrid bonds between facing dies.

11. The method of claim 1, wherein forming the core gap-fill layers further comprises planarizing the core gap-fill layers such that the layers are coplanar with the backs of the plurality of core dies.

12. A semiconductor device assembly, comprising:
a plurality of core dies, each core die having an active side facing downward, and each core die being surrounded peripherally by a first silicon oxide material that is coplanar with the active and a back side of the core die, the plurality of core dies connected in a vertical stack by hybrid bonds between adjacent core dies of the plurality;
a top die disposed over the plurality of core dies and hybrid bonded to a top one of the plurality of core dies, the top die having an active side facing downward, and the top die being surrounded peripherally by a second silicon oxide material that is coplanar with the active side of the top die and overlapping a back side of the top die, the second silicon oxide material being fusion bonded to the first silicon oxide material; and
a dummy silicon chip disposed over the top die and fusion bonded to the second oxide material overlapping the top die, the dummy silicon chip having sidewalls that are coplanar with outer edges of the peripheral first and second silicon oxide materials.

13. The semiconductor device assembly of claim 12, wherein the active side of the top die comprises a first plurality of pads.

14. The semiconductor device assembly of claim 13, wherein the back side of each core die comprises a second plurality of pads, and wherein the active side of each core die comprises a third plurality of pads.

15. The semiconductor device assembly of claim 14, wherein a subset of each of the first, second, and third plurality of pads are electrically disconnected from any active circuitry in the semiconductor device assembly.

16. The semiconductor device assembly of claim 12, wherein the dummy silicon chip comprises no electrical circuits.

17. The semiconductor device assembly of claim 12, wherein each of the plurality of core dies comprises a plurality of through silicon vias (TSVs) extending between the active side and the back side thereof.

18. The semiconductor device assembly of claim 12, wherein the top die is exclusive of any through silicon vias (TSVs).

19. The semiconductor device assembly of claim 12, wherein the first silicon oxide material peripherally surrounding each of the plurality of core dies is fusion bonded to the first silicon oxide material peripherally surrounding an adjacent one of the plurality of core dies.

20. A semiconductor device assembly, comprising:
a first semiconductor die having an active side facing downward and being surrounded peripherally by a first silicon oxide material that is coplanar with the active and a back side of the first semiconductor die;
a second semiconductor die disposed over and hybrid bonded to the first semiconductor die, the second semiconductor die having an active side facing downward and being surrounded peripherally by a second silicon oxide material that is coplanar with the active side of the second semiconductor die and that overlaps a back side of the second semiconductor die, the second silicon oxide material being fusion bonded to the first silicon oxide material; and
a dummy silicon chip disposed over the second semiconductor die and fusion bonded to the second oxide material overlapping the second semiconductor die, the dummy silicon chip having sidewalls that are coplanar with outer edges of the peripheral first and second silicon oxide materials.
